(19) United States
(12) Patent Application Publication
(10) Pub. No.: US 2018/0182905 A1
(43) Pub. Date: Jun. 28, 2018

(54) SOLAR CELL AND METHOD FOR MANUFACTURING THE SAME

(71) Applicant: LG Electronics Inc., Seoul (KR)

(72) Inventors: Jeongbeom NAM, SEOUL (KR); Joohyun KOH, SEOUL (KR); Jisoo KO, SEOUL (KR); Dohwan YANG, SEOUL (KR)

(73) Assignee: LG ELECTRONICS INC., SEOUL (KR)

(21) Appl. No.: 15/849,060

(22) Filed: Dec. 20, 2017

(30) Foreign Application Priority Data
Dec. 22, 2016 (KR) 10-2016-0176485

(51) Int. Cl. H01L 31/0216; H01L 31/0224; H01L 31/18; H01L 31/0236

(52) U.S. Cl. CPC H01L 31/02167; H01L 31/02363; H01L 31/1868; H01L 31/022441

(57) ABSTRACT

Disclosed is a solar cell including a plurality of first electrodes electrically connected to a plurality of first conductive regions; and a plurality of second electrodes electrically connected to a plurality of second conductive regions. The plurality of first conductive regions and the plurality of second conductive regions are spaced apart from an edge of a semiconductor substrate by a first interval, the plurality of first conductive regions and the plurality of second conductive regions are spaced apart from each other in a second direction crossing a first direction by a second interval, and the second interval is the same as or less than the first interval.

### CROSS-REFERENCE TO RELATED APPLICATION

This application claims priority to and the benefit of Korean Patent Application No. 10-2016-0176485, filed in the Korean Intellectual Property Office on Dec. 22, 2016, the entire contents of which are incorporated herein by reference.

### BACKGROUND OF THE INVENTION

### Field of the Invention

Embodiments of the invention relate to a solar cell and a method for manufacturing the same, and, more particularly, to a solar cell having an improved structure and a method for manufacturing the same.

### Description of the Related Art

Recently, as existing energy resources such as petroleum and coal are expected to be depleted, interest in alternative energy to replace them is increasing. Among them, solar cells are attracting attention as a next-generation battery that converts solar energy into electric energy.

In such solar cells, various layers and electrodes may be fabricated according to a design. Efficiency of solar cells may be determined by the design of these various layers and electrodes. In order to commercialize solar cells, it is required to overcome low efficiency, and various layers and electrodes are required to be designed and manufactured so as to maximize the efficiency of the solar cells.

### SUMMARY OF THE INVENTION

Therefore, embodiments of the invention have been made in view of the above problems, and embodiments of the invention are to provide a solar cell having excellent efficiency and reliability, and a method for manufacturing the solar cell.

A solar cell according to an embodiment of the invention includes: a semiconductor substrate; a control passivation layer on a surface of the semiconductor substrate; a plurality of first conductive regions extending in a first direction on the control passivation layer and having a first conductivity type; a plurality of second conductive regions extending in the first direction to be spaced apart from the plurality of first conductive regions on the control passivation layer and having a second conductivity type different from the first conductivity type; a plurality of first electrodes electrically connected to the plurality of first conductive regions; and a plurality of second electrodes electrically connected to the plurality of second conductive regions. The plurality of first conductive regions and the plurality of second conductive regions are spaced apart from an edge of the semiconductor substrate by a first interval, the plurality of first conductive regions and the plurality of second conductive regions are spaced apart from each other in a second direction crossing the first direction by a second interval, and the second interval is the same as or less than the first interval.

A solar cell according to another embodiment of the invention includes: a semiconductor substrate; a control passivation layer on a surface of the semiconductor substrate; a plurality of first conductive regions extending in a first direction on the control passivation layer and having a first conductivity type; a plurality of second conductive regions extending in the first direction to be spaced apart from the plurality of first conductive regions on the control passivation layer and having a second conductivity type different from the first conductivity type; a plurality of first electrodes electrically connected to the plurality of first conductive regions; and a plurality of second electrodes electrically connected to the plurality of second conductive regions. A stepped portion is formed on the surface of the semiconductor substrate, and at least one of the plurality of first electrodes and the plurality of second electrodes has a linear shape on the whole and partially includes a protrusion protruding to correspond to the stepped portion of the semiconductor substrate.

A method for manufacturing a solar cell according to an embodiment includes: forming a control passivation layer on a surface of a semiconductor substrate; forming a semiconductor layer on the control passivation layer, wherein the semiconductor layer including a plurality of first conductive regions extending in a first direction and having a first conductivity type, and a plurality of second conductive regions extending in the first direction to be spaced apart from the plurality of first conductive regions and having a second conductivity type different from the first conductivity type; and forming an electrode including a plurality of first electrodes electrically connected to the plurality of first conductive regions and a plurality of second electrodes electrically connected to the plurality of second conductive regions. The forming of the electrode includes: forming an electrode layer on the semiconductor layer by sputtering; forming a resist pattern on the electrode layer to correspond to a portion where the electrode is to be formed; etching a portion of the electrode layer where the resist pattern is not formed. A stepped portion is formed on the surface of the semiconductor substrate, and at least one of the plurality of first electrodes and the plurality of second electrodes has a linear shape on the whole and partially includes a protrusion protruding to correspond to the stepped portion of the semiconductor substrate.

According to embodiments of the invention, a photoelectric conversion area can be maximized and first and second electrodes can be patterned to have desired shapes by specifically limiting a structure and an arrangement of a conductive region and an electrode in a solar cell having a back contact structure. Thus, efficiency and reliability of the solar cell can be enhanced.

In this instance, electrodes formed by a sputtering process are patterned through an etching process using a resist pattern, a material cost can be reduced, a patterning process can be simplified, and stability of the patterning process can be improved. In this instance, the patterning can be stably performed by limiting a shape of the electrode. Accordingly, a solar cell having excellent efficiency and reliability can be manufactured by a simple process.

### BRIEF DESCRIPTION OF THE DRAWINGS

FIG. 1 is a cross-sectional view showing a solar cell according to an embodiment of the invention.

FIG. 2 is a rear plan view schematically showing the solar cell shown in FIG. 1.

FIG. 3 is an optical microscope photograph of a back surface of a solar cell according to an embodiment of the invention.

FIGS. 4A to 4E are views showing a method for manufacturing a solar cell according to an embodiment of the invention.

FIG. 5 is a rear plan view showing a plurality of solar cells connected by an interconnector to be applied to a solar cell panel including a solar cell according to an embodiment of the invention.

### DETAILED DESCRIPTION OF THE EMBODIMENTS

Hereinafter, embodiments of the invention will be described in detail with reference to accompanying drawings. However, embodiments of the invention are not limited thereto, and may be modified to other various embodiments.

In the drawings, illustration of portions unrelated to descriptions is omitted for clarity and simplicity. The same reference numerals designate the same or very similar elements throughout the specification. In the drawings, thicknesses, widths or the like of elements are exaggerated or reduced for clarity of descriptions, and thus, embodiments of the invention are not limited to the thickness, widths, or the like.

It will be understood that terms “comprise” and/or “comprising,” or “include” and/or “including” used in the specification do not preclude a presence or addition of one or more other elements. In addition, it will be understood that, when an element such as a layer, film, region, or plate is referred to as being “on” another element, it may be disposed “directly on” another element or may be disposed such that an intervening element is also present therebetween. Accordingly, when an element such as a layer, film, region, or plate is disposed “directly on” another element, this means that there is no intervening element between the elements.

Hereinafter, a solar cell and a method for manufacturing the same according to an embodiment of the invention will be described in detail with reference to the accompanying drawings.

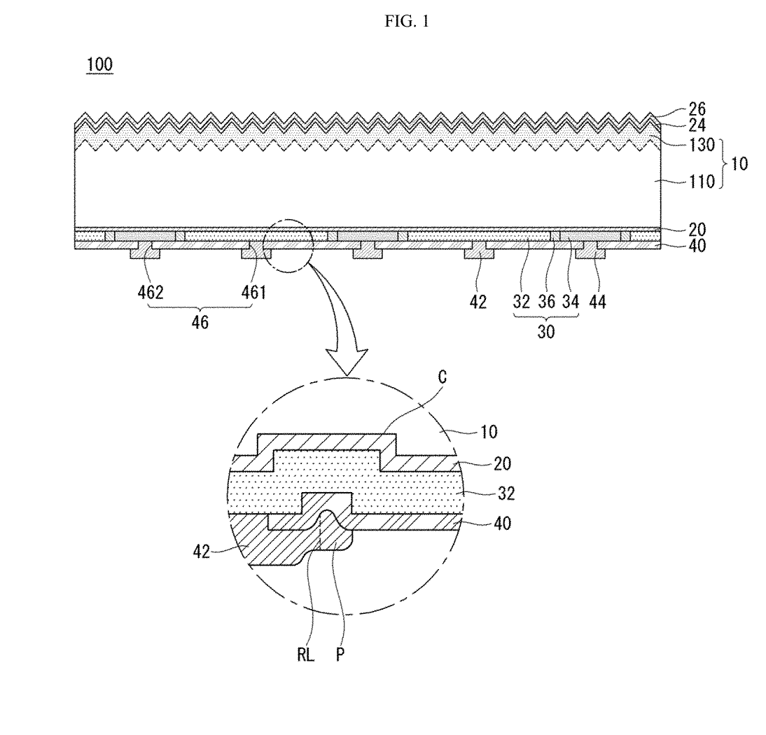

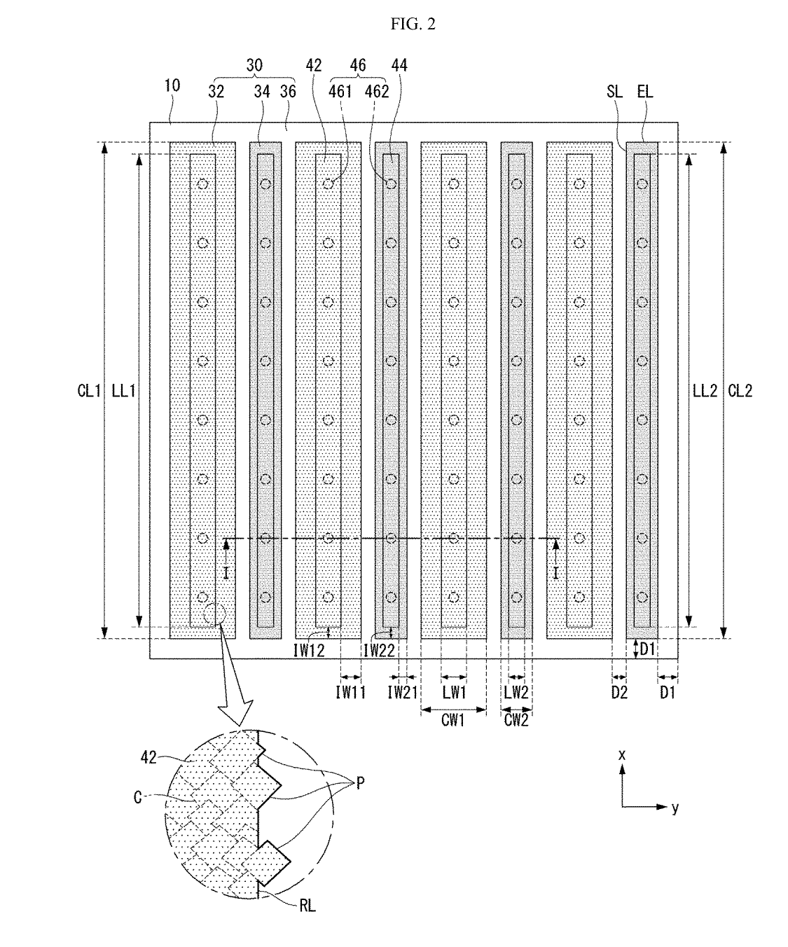

FIG. 1 is a cross-sectional view showing a solar cell according to an embodiment of the invention. For reference, FIG. 1 is the cross-sectional view taken along a line I-I in FIG. 2.

Referring to FIG. 1, a solar cell 100 according to an embodiment of the invention includes a semiconductor substrate 10, a dopant control passivation layer (or an oxide layer) (hereinafter referred to as “control passivation layer”) 20 on a surface (hereinafter referred to as “back surface”) of the semiconductor substrate 10, conductive regions 32 and 34 on the control passivation layer 20, and electrodes 42 and 44 electrically connected to the conductive regions 32 and 34. The conductive regions 32 and 34 include a first conductive region 32 having a first conductivity type and a second conductive region 34 having a second conductivity type different from the first conductivity type. The electrodes 42 and 44 include a plurality of first electrodes 42 electrically connected to the first conductive regions 32 and a plurality of second electrodes 44 electrically connected to the second conductive regions 34. In addition, the solar cell 100 may further include a front surface field region 130, a front passivation layer 24, an anti-reflection layer 26, a back passivation layer 40, or so on. This will be described in more detail.

The semiconductor substrate 10 may include a base region 110 including a second conductivity type dopant to have a second conductivity type at a relatively low doping concentration. The base region 110 may be formed of a crystalline semiconductor (e.g., a single-crystalline or a poly-crystalline semiconductor, e.g., single-crystalline or poly-crystalline silicon, particularly, single-crystalline silicon) including a second conductivity type dopant. The solar cell 100 based on the semiconductor substrate 10 or the base region 110 having a high degree of crystallinity and having few defects is excellent in electrical properties.

The second conductivity type may be a p-type or an n-type. For example, when the base region 110 is an n-type, the first conductive region 32 of a p-type that forms a junction (for example, a pn junction while interposing the control passivation layer 20), which generates carriers by a photoelectric conversion, with the base region 110 can be formed with a large area, and thus, a photoelectric conversion area can be increased. Also, the first conductive region 32 having a large area can effectively collect holes having a relatively slow moving speed, thereby contributing to an improvement of the photoelectric conversion efficiency. However, embodiments of the invention are not limited thereto.

In the embodiment, the front surface field region 130 positioned on or at the front surface of the semiconductor substrate 10 may be formed of a doped region having a second conductivity type the same as the base area 110 and doping with a doping concentration higher than that of the base area 110. The doped region may constitute a part of the semiconductor substrate 10.

An anti-reflection structure for minimizing a reflection may be formed at the front surface of the semiconductor substrate 10 where the front surface field region 130 is positioned. For example, a texturing structure having a concave/convex shape or unevenness in a form of a pyramid or the like may be provided as an anti-reflection structure. The texturing structure formed at the semiconductor substrate 10 may have a certain shape (e.g., a pyramid shape) having an outer surface formed along a specific crystal plane (e.g., (111) plane) of a semiconductor. When a surface roughness of the semiconductor substrate 10 is increased by the concave/convex structure on the front surface of the semiconductor substrate 10 formed by the texturing, a reflectance of light incident through the front surface of the semiconductor substrate 10 can be reduced to minimize an optical loss.

The back surface of the semiconductor substrate 10 may be formed of a relatively smooth and flat surface having a surface roughness smaller than that of the front surface by a mirror-polishing or the like. When the first and second conductive regions 32 and 34 are formed together on the back surface of the semiconductor substrate 10 as in the embodiment, properties of the solar cell 100 may be greatly varied according to properties of the back surface of the semiconductor substrate 10. As a result, the unevenness due to the texturing is not formed at the back surface of the semiconductor substrate 10, and thus, a passivation property at the back surface of the semiconductor substrate 10 can be improved, thereby improving the properties of the solar cell 100. However, the unevenness due to the texturing may be formed at the back surface of the semiconductor substrate 10 in some embodiments. Various other variations are possible.

The control passivation layer 20 may be formed on the back surface of the semiconductor substrate 10. For example, the control passivation layer 20 may be entirely formed on the back surface of the semiconductor substrate 10 and be in contact with the back surface of the semiconductor substrate 10. Then, the control passivation layer 20 can be easily formed without a patterning, a structure thereof can be simplified, and carriers can be stably transferred.

In the embodiment, the control passivation layer 20 positioned between the semiconductor substrate 10 and the conductive regions 32 and 34 acts as a dopant controller or a diffusion barrier that prevents the dopants of the conductive regions 32 and 34 from being excessively diffused into the semiconductor substrate 10. The control passivation layer 20 may include any of various materials capable of controlling the dopants and capable of transporting majority carriers. For example, the control passivation layer 20 may include an oxide, a nitride, a semiconductor, a conductive polymer, or the like. For example, the control passivation layer 20 may be an oxide layer, and, more particular, a silicon oxide layer including a silicon oxide. The silicon oxide layer has an excellent passivation property and carriers are smoothly transferred through the silicon oxide layer.

The control passivation layer 20 may have a small thickness so that carriers can be stably transferred. For example, a thickness of the control passivation layer 20 may be 5 nm or less (more particularly, 2 nm or less, for example, 0.5 nm to 2 nm). If the thickness of the control passivation layer 20 is more than 5 nm, the carriers may be not transferred and the solar cell 100 may not operate. If the thickness of the control passivation layer 20 is less than 0.5 nm, the control passivation layer 20 having a desired quality may be difficult to be formed. The thickness of the control passivation layer 20 may be 2 nm or less (more particularly, 0.5 nm to 2 nm) so that the carriers can be smoothly transferred more. In this instance, the thickness of the control passivation layer 20 may be 0.5 nm to 1.5 nm. However, embodiments of the invention are not limited thereto, and the thickness of the control passivation layer 20 may have any of various values.

The semiconductor layer 30 including the conductive regions 32 and 34 may be positioned on the control passivation layer 20. In one example, the semiconductor layer 30 may be in contact with the control passivation layer 20 to simplify a structure and allow carriers to be easily transferred.

In the embodiment, the semiconductor layer 30 includes the first conductive region 32 having a first conductivity type dopant to have a first conductivity type, and the second conductive region 34 having a second conductivity type dopant to have a second conductivity type. The first conductive region 32 and the second conductive region 34 may be positioned together at or in the semiconductor layer 30 continuously formed on the control passivation layer 20, and thus, may be coplanar or positioned on the same plane. The first conductive region 32 and the second conductive region 34 are spaced apart from each other. In a portion where the first and second conductive regions 32 and 34 are not formed, the barrier region 36 may be positioned.

The first conductive region 32 may constitute an emitter region forming a pn junction (or a pn tunnel junction) with the base region 110, which interposes the control passivation layer 20 between the first conductive region 32 and the base region 110, to generate carriers by a photoelectric conversion. The second conductive region 34 may constitute a back surface field region for generating a back surface field to prevent carriers from being lost due to a recombination at the back surface of the semiconductor substrate 10.

In this instance, the first conductive region 32 may include a semiconductor (for example, silicon) including a first conductivity type dopant to have a conductivity type opposite to that of the base region 110. The second conductive region 34 may include a second conductivity type dopant to have a conductivity type the same as that of the base region 110, and a doping concentration of the second conductive region 34 may be higher than that of the base region 110. In the embodiment, the first and second conductive regions 32 and 34 may be formed of a semiconductor layer, which is formed on the semiconductor substrate 10 (more particularly, on the control passivation layer 20) to be separated from the semiconductor substrate 10 and is doped with the first or second conductivity type dopant. Accordingly, the first and second conductive regions 32 and 34 may be formed of a semiconductor layer having a crystal structure different from that of the semiconductor substrate 10 so that the first and second conductive regions 32 and 34 can be easily formed on the semiconductor substrate 10. For example, the first and second conductive regions 32 and 34 may be formed by doping an amorphous semiconductor, a micro-crystalline semiconductor, or a poly-crystalline semiconductor (e.g., amorphous silicon, micro-crystalline silicon, or poly-crystalline silicon) or the like, which can be easily manufactured by any of various methods, such as, a deposition, with a first or second conductivity type dopant. In particular, when the first and second conductive regions 32 and 34 include a poly-crystalline semiconductor, a carrier mobility can be high. The first or second conductivity type dopant may be doped during a process of forming the semiconductor layer 30 to be included in the semiconductor layer 30 or may be doped by any of various doping methods, such as, a thermal diffusion method, an ion implantation method, or the like, after forming the semiconductor layer 30.

Any of various materials, which may be doped to the semiconductor layer 30 to exhibit an n-type or a p-type, may be used for the first or second conductivity type dopant. When the first or second conductivity type dopant is a p-type, a group III element, such as, boron (B), aluminum (Al), gallium (Ga), indium (In) or so on, may be used. When the first or second conductivity type dopant is an n-type, a group V element, such as, phosphorus (P), arsenic (As), bismuth (Bi), antimony (Sb) or so on, may be used. In one example, one of the first and second conductivity type dopants may be boron (B) and the other of the first and second conductivity type dopants may be phosphorus (P).

The barrier region 36 may be positioned between the first conductive region 32 and the second conductive region 34 to separate the first conductive region 32 and the second conductive region 34 to each other. If the first conductive region 32 and the second conductive region 34 are in contact with each other, a shunt may occur, thereby deteriorating a performance of the solar cell 100. Accordingly, in the embodiment, an unnecessary shunt can be prevented by positioning the barrier region 36 between the first conductive region 32 and the second conductive region 34.

An insulating material, which is not doped, (i.e., an undoped insulating material) (e.g., an oxide, a nitride) or so on may be used for the barrier region 36. Alternatively, the barrier region 36 may include an intrinsic semiconductor. In this instance, the first conductive region 32, the second conductive region 34, and the barrier region 36 are formed of the same semiconductor layer (for example, an amorphous silicon layer, a micro-crystalline silicon layer, a poly-crystalline silicon layer), which is continuously formed so that side surfaces of them are in contact with each other. The barrier region 36 may be formed of an i-type (intrinsic) semiconductor material that substantially does not include dopants. For example, a semiconductor layer including a semiconductor material may be formed, and then, a first conductivity type dopant may be doped to a portion of the semiconductor layer to form a first conductive region 32 and a second conductivity type dopant may be doped to another portion of the semiconductor layer. Then, a region where the first conductive region 32 and the second conductive region 34 are not formed may constitute the barrier region 36. In this instance, a manufacturing method for the first conductive region 32, the second conductive region 34, and the barrier region 36 can be simplified.

However, embodiments of the invention are not limited thereto. Accordingly, the barrier region 36 may be formed by any of various methods and may have any of various thicknesses and any of various shapes. The barrier region 36 may be a trench of an empty space. Various other variations are possible.

The back passivation layer 40 may be formed on the first and second conductive regions 32 and 34 and the barrier region 36 at the back surface of the semiconductor substrate 10. For example, the back passivation layer 40 may be in contact with the first and second conductive regions 32 and 34 and the barrier region 36 to simplify a structure of the solar cell 100.

The back passivation layer 40 has contact holes 46 for electrically connecting the conductive regions 32 and 34 to the electrodes 42 and 42. The contact hole 46 includes first contact holes 461 for connecting the first conductive region 32 and the first electrode 42 and second contact holes 462 for connecting the second conductive region 34 and the second electrode 44. As a result, the back passivation layer 40 may prevent the first conductive region 32 and the second conductive region 34 from being connected to the electrode not to be connected (that is, the second electrode 44 in a case of the first conductive region 34, and the first electrode in a case of the second conductive region 34). In addition, the back passivation layer 40 may passivate the first and second conductive regions 32 and 34 and/or the barrier region 36.

The front passivation layer 24 and/or the anti-reflection layer 26 is formed on the front surface of the semiconductor substrate 10 (more particularly, on the front surface field region 130 formed at the front surface of the semiconductor substrate 10). However, embodiments of the invention are not limited thereto, and another insulating layer having a different stacked structure may be formed on the front surface field region 130.

The front passivation layer 24 and the anti-reflection layer 26 may be formed on a substantially entire portion of the front surface of the semiconductor substrate 10. The back passivation layer 40 may be formed entirely on the back surface of the semiconductor layer 30 except for the contact hole 46.

The front passivation layer 24 or the back passivation layer 40 may be contact with the semiconductor substrate 10 or the semiconductor layer 30 to passivate a surface or a bulk of the semiconductor substrate 10 or the semiconductor layer 30. Accordingly, recombination sites of minority carriers can be removed, and open-circuit voltage of the solar cell 100 can be enhanced. The anti-reflection layer 26 can reduce a reflectance of light incident to the front surface of the semiconductor substrate 10 and can increase an amount of light reaching the pn junction. Accordingly, short circuit current Isc of the solar cell 100 can be increased.

The front passivation layer 24, the anti-reflection layer 26, and the back passivation layer 40 may be formed of any of various materials. For example, the front passivation layer 24, the anti-reflection layer 26, or the passivation layer 40 may be formed of a single layer or have a multilayer structure having at least two layers, which includes at least one selected from a group consisting of a silicon nitride layer, a silicon nitride layer including hydrogen, a silicon oxide layer, a silicon oxynitride layer, an aluminum oxide layer, a silicon carbide layer, MgF₂, ZnS, TiO₂, and CeO₂.

For example, in the embodiment, the front passivation layer 24 and/or the anti-reflection layer 26, and the back passivation layer 40 may not have a dopant or the like in order to have good insulating and passivation properties. However, embodiments of the invention are not limited thereto.

The front passivation layer 24, the anti-reflection layer 26, and the back passivation layer 40 may have thicknesses greater than a thickness of the control passivation layer 20. Thus, insulating and passivation properties can be improved. Various other variations are possible.

The first electrode 42 may fill at least a part of the first contact hole 461 of the back passivation layer 40 to be electrically connected to (for example, to be in contact with) the first conductive region 32. The second electrode 44 may fill at least a part of the second contact hole 462 of the back passivation layer 40 to be electrically connected to (for example, to be in contact with) the second conductive region 34. The first and second electrodes 42 and 44 may include a single layer or a plurality of layers. In this instance, the first and second electrodes 42 and 44 may be formed of a plurality of layers so as to satisfy various properties.

In the embodiment, in the solar cell 100 where the first and second conductive regions 32 and 34 and/or the barrier region 36, and the first and second electrodes 42 and 44 are formed together on a surface (for example, the back surface) of the semiconductor substrate 10, arrangements and structures of the first and second conductive regions 32 and 34 and/or the barrier region 36, and the first and second electrodes 42 and 44 are limited for improving efficiency and reliability of the solar cell 100. The specific arrangements thereof will be described in detail with reference to FIG. 2 together with FIG. 1.

FIG. 2 is a rear plan view schematically showing the solar cell shown in FIG. 1. For simplicity and clarity, the back passivation layer 40 is not shown in FIG. 2.

Referring to FIGS. 1 and 2, in the embodiment, a plurality of first conductive regions 32 extend in a first direction (e.g., an x-direction in the drawing) so as to have a stripe shape, a plurality of second conductive regions 34 extend in the first direction so as to have a stripe shape, and the first conductive regions 32 and the second conductive regions 34 are alternately disposed in a second direction (e.g., a y-axis direction in the drawing) crossing (for example, perpendicular to) the first direction. Similarly, a plurality of first electrodes 42 extend in the first direction so as to have a stripe shape, a plurality of second electrodes 44 extend in the first direction so as to have a stripe shape, and the first electrodes 42 and the second electrodes 44 are alternately disposed in the second direction.

More particularly, the plurality of first conductive regions 32 may be not connected to each other, and thus, may be separated from each other in the second direction. The plurality of second conductive regions 34 may be not connected to each other, and thus, may be separated from each other in the second direction. Similarly, the plurality of first electrodes 42 may be not connected to each other, and thus, may be separated from each other in the second direction. The plurality of second electrodes 44 may be not connected to each other, and thus, may be separated from each other in the second direction. For example, each of the first and second conductive regions 32 and 34 and the first and second electrodes 42 and 44 may be formed of one body or a single body longitudinal extended in the first direction without a disconnection or a cut portion.

In this instance, the contact holes 46 may be formed such that a part of the first and second electrodes 42 and 44 are electrically connected to (for example, are in contact with) the first and second conductive regions 32 and 34, respectively. For example, a plurality of first contact holes 461 may be formed for each of the first conductive regions 32, and a plurality of second contact holes 462 may be formed for each of the second conductive regions 34. Since properties of the first and second conductive regions 32 and 34 may be varied in a portion where the contact hole 46 is formed in a process of forming the contact hole 46, an area of each of the contact holes 46 is reduced in the embodiment. Instead, a number of contact holes 46 is increased for a sufficient electrical connection. However, embodiments of the invention are not limited thereto. As another example, a single contact hole 46 extending in the first direction may be formed to correspond to the first or second conductive regions 32 or 34. Various other variations are possible.

In the embodiment, the first and second conductive regions 32 and 34 may be spaced apart from an edge of the semiconductor substrate 10 by a first interval D1. For example, each of ends EL of the first and second conductive regions 32 and 34 may be spaced apart from each of the edges of the semiconductor substrate 10 by the first interval D1 in the first direction, and each of edges SL of the first and second conductive regions 32 and 34 may be spaced apart from each of the edges of the semiconductor substrate 10 by the first interval D1 in the second direction. Contrary to the above, if the first and second conductive regions 32 and 34 are extended to the edge of the semiconductor substrate 10, the edge of the semiconductor substrate 10 is doped, and an edge isolation may be not sufficient and an undesired shunt may occur. In the drawings and the descriptions, it is exemplified that each of the end EL and the edge SL of the first and second conductive regions 32 and 34 is spaced apart from the edge of the semiconductor substrate 10 by the same first interval D1 in the first direction and the second direction. However, embodiments of the invention are not limited thereto. An interval between the ends EL of the first and second conductive regions 32 and 34 of the edge of the semiconductor substrate 10 in the first direction may be different from an interval between the edges SL of the first and second conductive regions 32 and 34 of the edge of the semiconductor substrate 10 in the second direction.

The first conductive region 32 and the second conductive region 34 are spaced apart from each other in the second direction by a second interval D2. The second interval D2 may be the same as or less than the first interval D1 (in particular, an interval between each of the ends EL of the first and second conductive regions 32 and 34 and the edge of the semiconductor substrate 10 in the first direction). In particular, the second interval D2 may be less than the first interval D1. It is because the first conductive region 32 and the second conductive region 34 may be stably spaced from each other in a doping process even when the second interval D2 is small. In addition, by reducing the second interval D2, an area of the first and second conductive regions 32 and 34 can be maximized, thereby sufficiently securing an area directly contributing to a photoelectric conversion.

As an example, the first interval D1 may be in a range of 100 μm to 500 μm and the second interval D2 may be in a range of 50 μm to 200 μm. The first interval D1 is limited so that the area of the first and second conductive regions 32 and 34 can be sufficiently secured while the edge isolation is stably performed. The second interval D2 is limited so as to sufficiently secure the area of the first and second conductive regions 32 and 34 while preventing shunting between the first and second conductive regions 32 and 34. However, embodiments of the invention are not limited thereto.

In the embodiment, the barrier region 36 may be entirely positioned at a portion on the control passivation layer 20 except for a portion where the first and second conductive regions 32 and 34 are formed. Then, the barrier region 36 may surround all ends and edges of each of the first and second conductive regions 32 and 34, and may have a shape that entirely surrounds each of the first and second conductive regions 32 and 34 and isolates and separates the first and second conductive regions 32 and 34 from each other. The barrier region 36 is formed entirely along the edge of the semiconductor substrate 10 between the first and second conductive regions 32 and 34 and the edge of the semiconductor substrate 10, and is entirely positioned between the first and second conductive regions 32 and 34.

In this instance, an area of the first conductive region 32 may be larger than an area of the second conductive region 34. Then, the area of the first conductive region 32 acting as the emitter region can be sufficiently secured. In one example, the areas of the first conductive region 32 and the second conductive region 34 may be adjusted by varying their widths. That is, a width CW1 of the first conductive region 32 may be greater than a width CW2 of the second conductive region 34. A length CL1 of the first conductive region 32 and a length CL2 of the second conductive region 34 are substantially the same as each other and ends of the first and second conductive regions 32 and 34 may be positioned at the same position. Then, the areas of the first and second conductive regions 32 and 34 can be different from each other while maximizing the areas of the first and second conductive regions 32 and 34.

In one example, the first interval D1 may be smaller than the width CW1 of the first conductive region 32 and the width CW2 of the second conductive region 34 in the second direction. As a result, the area of the first and second conductive regions 32 and 34 can be sufficiently secured.

The first electrode 42 has a width LW1 that is smaller than the width CW1 of the first conductive region 32 and a length LL1 that is smaller than the length CL1 of the first conductive region 32. Thus, an entire portion of the first electrode 42 overlaps the first conductive region 32. The second electrode 44 has a width LW2 that is smaller than the width CW2 of the second conductive region 34 and a length LL2 that is smaller than the length CL2 of the second conductive region 34. Thus, an entire portion of the second electrode 44 overlaps the second conductive region 34. That is, the entire portion of the first electrode 42 overlaps the first conductive region 32 and the first electrode 42 does not deviate from the first conductive region 32, and the entire portion of the second electrode 44 overlaps the second conductive region 34 and the second electrode 44 does not deviate from the second conductive region 34. Thus, the first and second conductive regions 32 and 34 and the first and second electrodes 42 and 44 can be electrically connected to each other without any alignment error even when there is a process error or the like.

When the widths LW1 and LW2 of the first and second electrodes 42 and 44 are increased, resistance of the first and second electrodes 42 and 44 can be reduced by a large area, while a distance between the first and second electrodes 42 and 44 may be decrease and thus the first and second electrodes 42 and 44 may be not separated from each other and an undesired short may occur if a patterning is not performed well. In consideration of this, each of the widths LW1 and LW2 of the first and second electrodes 42 and 44 may have a constant or limited value. For example, the width LW2 of the second electrode 44 may be 160 to 280 μm. The range is limited in consideration with a size of the contact hole 46 and a process margin, together with resistance and a possibility of a short circuit. The width LW1 of the first electrode 42 may be the same as or greater than the width LW2 of the second electrode 44. For example, the width LW1 of the first electrode 42 may be greater than the width LW2 of the second electrode 44. For example, the width LW1 of the first electrode 42 may be 160 to 400 μm (e.g., 200 to 300 μm). However, embodiments of the invention are not limited thereto.

In this instance, each of a distance between the edge SL of the first conductive region 32 and the edge of the first electrode 42 in the second direction, which will be referred to as a first widthwise distance IW11, and a distance between the edge SL of the second conductive region 34 and the edge of the second electrode 44 in the second direction, which will be referred to as a second widthwise distance IW21, may be the same as or smaller than the second interval D2. Particularly, each of the first widthwise distance IW11 and the second widthwise distance IW21 may be smaller than the second interval D2. For reference, the first widthwise distance IW11 and the second widthwise distance IW21 are based on one side. Thus, one side of the first electrode 42 may be spaced apart from one side of the first conductive region 32 by the first widthwise distance IW11, and the other side of the first electrode 42 may be spaced apart from the other side of the first conductive region 32 by the first widthwise distance IW11. Also, one side of the second electrode 44 may be spaced apart from one side of the second conductive region 34 by the second widthwise distance IW21, and the other side of the second electrode 44 may be spaced apart from the other side of the second conductive region 34 by the second widthwise distance IW21.

When the first widthwise distance IW11 and the second widthwise distance IW21 are the same as or smaller than the second interval D2 as described above, the area of the first and second electrodes 42 and 44 can be sufficiently secured and electrical properties can be improved. In addition, the second interval D2 is secured relatively large, and thus, a shunt between the first and second conductive regions 32 and 34 can be effectively prevented.

Each of a distance between the end EL of the first conductive region 32 and the end of the first electrode 42 in the first direction, which will be referred to as a first lengthwise distance IW12, and a distance between the end EL of the second conductive region 34 and the end of the second electrode 44 in the first direction, which will be referred to as a second lengthwise distance IW22, may be the same as or smaller than the second interval D2. Particularly, each of the first lengthwise distance IW12 and the second lengthwise distance IW22 may be smaller than the second interval D2. For reference, the first lengthwise distance IW12 and the second lengthwise distance IW22 are based on one end. Thus, one end of the first electrode 42 may be spaced apart from one end of the first conductive region 32 by the first lengthwise distance IW12, and the other end of the first electrode 42 may be spaced apart from the other end of the first conductive region 32 by the first lengthwise distance IW12. Also, one end of the second electrode 44 may be spaced apart from one end of the second conductive region 34 by the second lengthwise distance IW22, and the other end of the second electrode 44 may be spaced apart from the other end of the second conductive region 34 by the second lengthwise distance IW22.

When the first lengthwise distance IW12 and the second lengthwise distance IW22 are the same as or smaller than the second interval D2 as described above, the area of the first and second electrodes 42 and 44 can be sufficiently secured and electrical properties can be improved. In addition, the second interval D2 is secured relatively large, and thus, a shunt between the first and second conductive regions 32 and 34 can be effectively prevented.

In the first conductive region 32 having the relatively large width CW1 and the first electrode 42 connected to the first conductive region 32, the first widthwise distance IW11 may be the same as or greater than the first lengthwise distance IW12. For example, the first widthwise distance IW11 may be greater than the first lengthwise distance IW12. Since the first conductive region 32 and the first electrode 42 are positioned with a large number in the second direction, an alignment problem may occur in the second direction rather than the first direction during the alignment process. In consideration of this, the first widthwise distance IW11 may be relatively large, and thus, a problem due to a process error or the like can be prevented.

However, in the second conductive region 34 having the relatively small width CW2 and the second electrode 44 connected to the second conductive region 34, the second widthwise distance IW21 may be the same as, less than, or greater than the second lengthwise distance IW22. This is because the second widthwise distance IW21 may vary in consideration of the width of the second conductive region 34 since the second conductive region 34 has the relatively small width CW2. For example, the second widthwise distance IW21 may be the same as or less than the second lengthwise distance IW22 (more particularly, the second widthwise distance IW21 may be less than the second lengthwise distance IW22) so that the second electrode 44 may have a sufficient area. However, embodiments of the invention are not limited thereto.

The width LW1 of the first electrode 42 in the second direction may be greater than the width LW2 of the second electrode 44 in the second direction. This is because the width LW1 of the first electrode 42 may be relatively large since the width CW1 of the first conductive region 32 is large. In this instance, the first widthwise distance IW11 in the second direction may be greater than the second widthwise distance IW21. On the contrary, if the second widthwise distance IW21 is greater than the first widthwise distance IW11, an electric property may be deteriorated because the width LW2 of the second electrode 44 becomes small and the area of the second electrode 44 becomes insufficient, or a pattering may not be performed well because the width LW1 of the first electrode 42 is increased and the distance between the first electrode 42 and the second electrode 44 is reduced.

In the embodiment, each of the first conductive region 32, the second conductive region 34, and the first and second electrodes 42 and 44 may have a linear shape (or a straight shape) having a uniform width on the whole. Here, the phrase of “having a linear shape having a uniform width on the whole” means that a ratio of a length of a portion having a uniform linear shape to the whole length is 50% or more, and/or a difference between the shortest width and the longest width is 20% or less. Accordingly, the first and second electrodes 42 and 44 do not have separate pad portions having a width greater than other portions. This is because a manufacturing process, a thickness of the first and second electrodes 42 and 44, and so on are considered in the embodiment. This will be described in more detail.

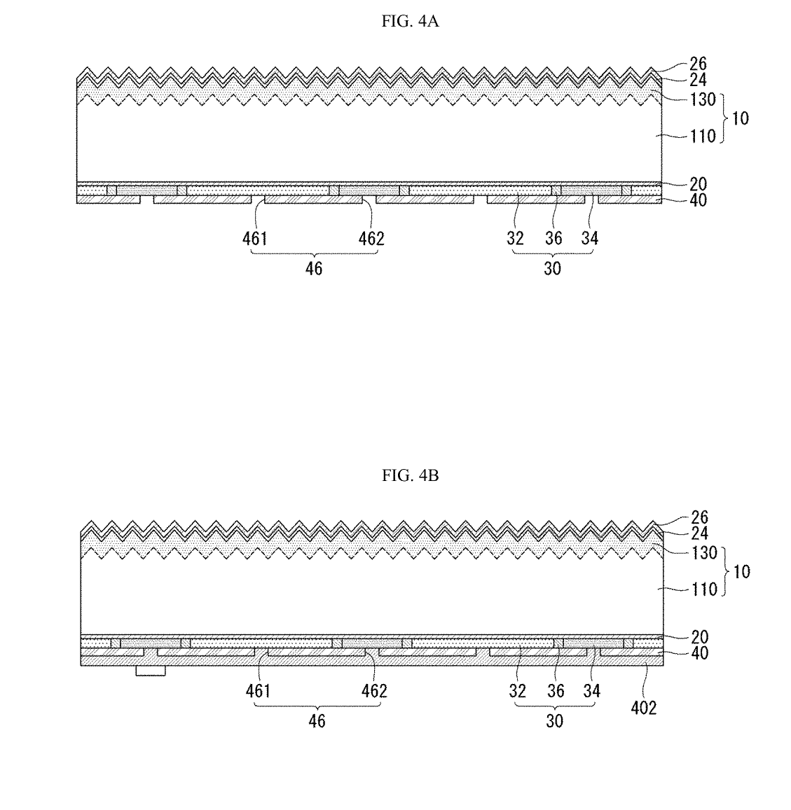

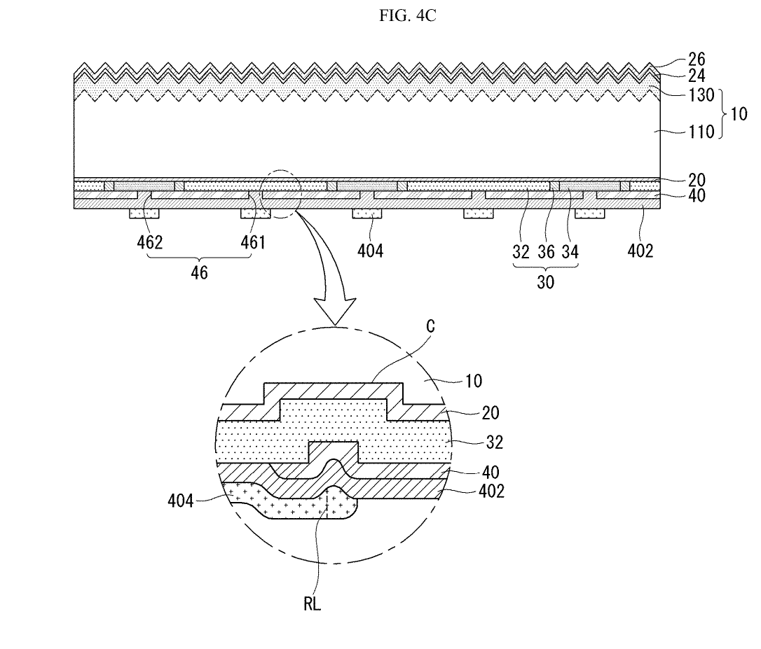

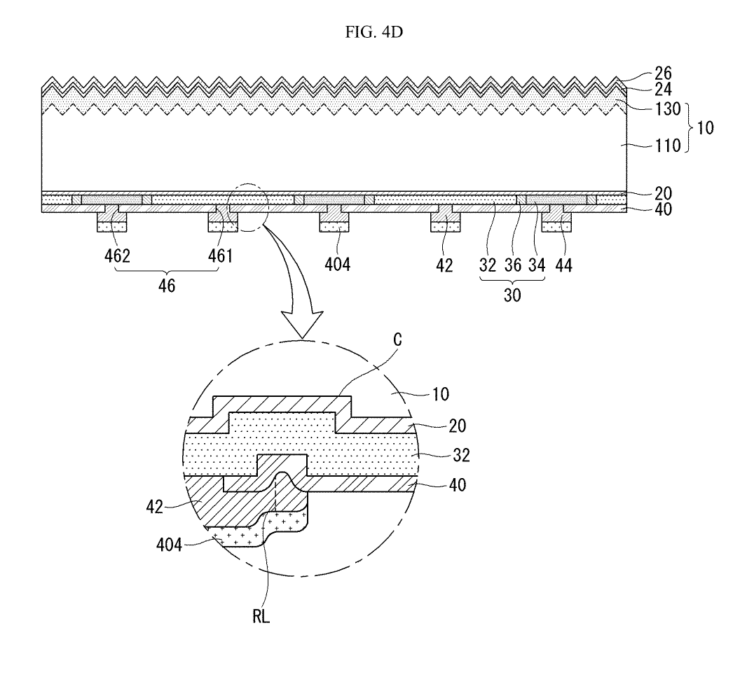

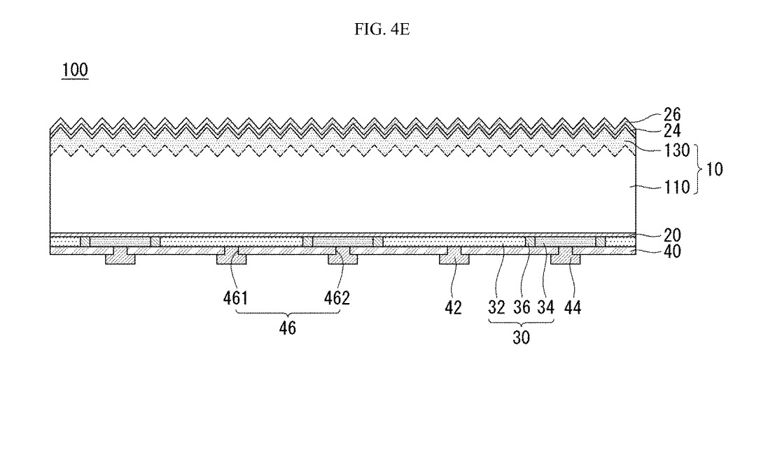

In the embodiment, thicknesses (total thicknesses) of the first and second electrodes 42 and 44 may be smaller than each of the first interval D1, the second interval D2, the width CW1 of the first conductive region 32, the width CW2 of the second conductive region 34, the width LW1 of the first electrode 42, the width LW2 of the second electrode 44, the first and/or second widthwise distance IW11 and/or IW21, the first and/or second lengthwise distance IW12 and/or IW22. Then, the thicknesses of the first and second electrodes 42 and 44 are reduced to minimize a material cost. In the embodiment, the first and second electrodes 42 and 44 are formed by forming a metal layer (or an electrode layer) 402 (see FIG. 4B) through a sputtering and then removing a part of the metal layer 402 through an etching process. In this instance, when the first and second electrodes 42 and 44 with a large number are positioned together on the back surface in the embodiment, it is advantageous that the first and second electrodes 42 and 44 have a minimum thickness in order to precisely remove desired portions of the metal layer 402 without an error. For example, the thicknesses of the first electrode 42 and the second electrode 44 may be 1 μm or less. The etching can be performed uniformly and effectively within the above range, and thus, an electrical property can be sufficient. When the thicknesses of the first and second electrodes 42 and 44 are small, a problem of bending of the semiconductor substrate 10 that may be induced by a thermal stress, or so on (especially, that may be greatly induced in the solar cell 100 having the back contact structure where the first and second electrodes 42 and 44 are positioned on the same surface) can be effectively prevented.

In the patterning performed using the etching as described above, the first and second electrodes 42 and 44 can be precisely patterned and a portion of the metal layer 402 to be removed can be completely removed to have a desired pattern when the first and second electrodes 42 and 44 have a linear shape having a uniform width on the whole. A manufacturing process of the first and second electrodes 42 and 44 will be described later in more detail. In addition, the first and second electrodes 42 and 44 have the linear shape, and thus, carriers can be uniformly and effectively collected at a large area. The first and second conductive regions 32 and 34 and the first and second electrodes 42 and 44 have the linear shape, and thus, they can be precisely and stably aligned.

On the other hand, when an electrode is formed by a printing or the like, there is a problem that a metal content of the electrode is lower than that of the electrode formed by a sputtering or a high heat treatment is required for firing. Also, when an electrode is formed by plating or the like, current may be not uniform depending on the position of the electrode and the plating may be not uniform. In order to prevent the above problem, a width of the electrode should be gradually increased or decreased and an additional pad portion for applying the current should be provided. As a result, it may be difficult to effectively collect carriers with a large area and an area of a portion where carriers are not directly collected may be relatively large due to the pad portion. Also, the electrode has a thickness of 10 μm or more in the case of printing, and the electrode has a thickness of 25 μm in the case of plating in consideration of electrical properties. Thus, the electrode formed by the printing or the plating has a thickness greater than that in the embodiment. Accordingly, in the printing or the plating, a material cost may increase, and the semiconductor substrate may be bent by a thermal stress, which may be greatly induced in the structure where the first and second electrodes are positioned on the same surface.

As described above, in the embodiment, the first and second electrodes 42 and 44 have the linear shape on the whole, but may include a protrusion P according to a polishing mark of the semiconductor substrate 10 at both ends and/or both edges of the first and second electrodes 42 and 44. For example, it is exemplified that the protrusion P is formed at the first electrode 42 in an enlarged circle of FIGS. 1 and 2 and the following descriptions, however it is only for illustration. Thus, the protrusions P may be formed at at least one of the first and second electrodes 42 and 44. This will be described in detail with reference to FIGS. 1 and 2.

As described above, the back surface of the semiconductor substrate 10 may be polished by a mirror polishing or the like in consideration of passivation properties and the like. In this instance, on the back surface of the semiconductor substrate 10, there is a portion where the etching is performed more by a difference in etching rates depending on crystal planes. As a result, a stepped portion may be formed on the back surface of the semiconductor substrate 10. The stepped portion may be formed by a concave portion C which is recessed into the semiconductor substrate 10. The concave portion C may be formed by a polishing mark. For example, an etching speed of (100) plane is greater than that of (111) plane, and the (100) plane may constitute the concave portion C. In this instance, the concave portion C may have a planar shape of a quadrangle (e.g., a rectangle, more particularly, a square). An edge of the concave portion C may be inclined to the edge of the semiconductor substrate 10 in a plan view. For example, a depth of the concave portion C may be greater than the thicknesses of the first and second electrodes 42 and 44, and may be, for example, 5 μm or less (as an example, greater than 1 μm and smaller than 3 μm).

When the concave portion C existing on the back surface of the semiconductor substrate 10 is positioned over a patterning reference line RL of the first electrode 42, which is desired, as described above, the first electrode 42 entirely fills the concave portion C. This is because a pattern resist 404 (see FIG. 4C) used when the first electrode 42 is formed to entirely fill the concave portion C since the first electrode 42 is thin. This will be described in more detail in a manufacturing method for the solar cell 100. As described above, a portion of the first electrode 42 that extends beyond the patterning reference line RL to an outside may constitutes the protrusion P.

As described above, since the concave portion C has a planar shape of a quadrangle (e.g., a rectangle, more particularly, a square), the protrusion P may have a planar shape for constituting a part of a quadrangle (e.g., a rectangle, more particularly, a square). Accordingly, the planar shape of the protrusion P has at least two sides intersecting (for example, perpendicular to) each other, which are inclined to the edges of the semiconductor substrate 10. For example, the planar shape of the protrusion P may have a triangular shape having a right angle or a quadrangular shape having two right angles. A length of a long side of the protrusion P may be 25 μm or less. However, embodiments of the invention are not limited thereto, and a shape of the protrusion P may have any of various shapes and a size of the protrusion P may have any of various values.

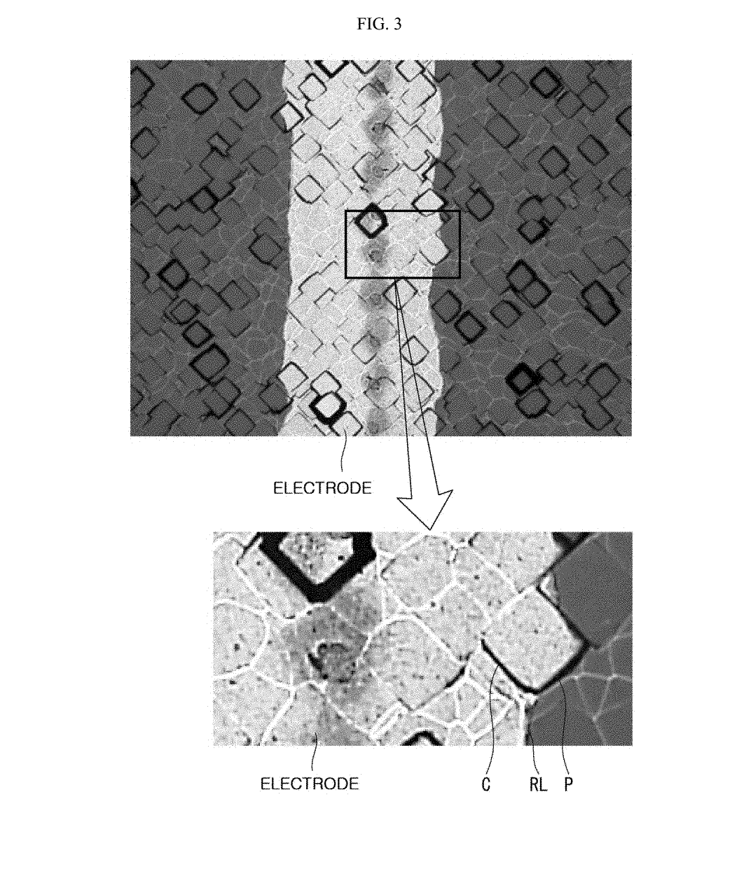

Accordingly, the first and second electrodes 42 and 44 may have a shape having the linear shape on the whole and having the protrusion P partially protruding. Such a protrusion P may be confirmed by an optical microscope, a three-dimensional (3D) microscope, or the like. Referring to FIG. 3, which is an optical microscope photograph of the back surface of the solar cell 100 according to the embodiment, it can be seen that the electrode has a shape having a general linear shape and having a protrusion P partially protruding. This is because the first and second electrodes 42 and 44 are formed by patterning the metal layer 402 with a small thickness after the metal layer 402 is formed. The reason why the protrusion P is formed will be described in more detail later in a manufacturing method for the solar cell 100.

When light is incident to the solar cell 100 according to the embodiment, electrons and holes are generated by a photoelectric conversion at the pn junction formed between the base region 110 and the first conductive region 32, and the generated holes and electrons are transferred to the first conductive region 32 and the second conductive region 34 passing through the control passivation layer 20 and then are transferred to the first and second electrodes 42 and 44, respectively, thereby generating electrical energy.

In the solar cell 100 having the back contact structure in which the electrodes 42 and 44 are formed on the back surface of the semiconductor substrate 10 and the electrodes 42 and 44 are not formed on the front surface of the semiconductor substrate 10 as in the embodiment, a shading loss at the front surface of the substrate 10 can be minimized. Thus, efficiency of the solar cell 100 can be improved. Since the control passivation layer 20 is disposed between the first and second conductive regions 32 and 34 and the semiconductor substrate 10, the first and second conductive regions 32 and 34 are formed of a separate layer different from the semiconductor substrate 10. As a result, a loss due to a recombination can be minimized as compared with a case where a doped region formed by doping the semiconductor substrate 10 with the dopants is used as the conductive region.

In this instance, in the solar cell 100 having the back contact structure in which the first and second electrodes 42 and 44 are disposed on the same surface, a photoelectric conversion area can be maximized and the first and second electrodes 42 and 44 can be patterned to have desired shapes by specifically limiting a structure and an arrangement of the conductive regions 32 and 34 and the electrodes 42 and 44. Thus, efficiency and reliability of the solar cell 100 can be enhanced.

Hereinafter, a method for manufacturing the solar cell 100 described above will be described in detail with reference to FIGS. 4A to 4E. For simplicity and clarity, portions that are already described in the above will be omitted and portions that are not described in the above will be described in detail.

FIGS. 4A to 4E are views showing a method for manufacturing a solar cell according to an embodiment of the invention.

First, as shown in FIG. 4A, a control passivation layer 20, a semiconductor layer 30 including first and second conductive regions 32 and 34 and a barrier region 36, a back passivation layer 40 having contact holes 46, a front surface field region 130, a front passivation layer 24, and an anti-reflection layer 26 are formed on a semiconductor substrate 10. Any of various methods may be applied to a method for forming them, and an order of them may be variously modified.

In this instance, a back surface of the semiconductor substrate 10 may be mirror-polished to improve passivation properties. Any of various methods known as mirror-polishing may be used. A polishing mark may be formed by crystal planes having different etch rates during the mirror-polishing. For example, a concave portion C depressed more than other portions may be formed at a portion where (100) crystal planes having an etching rate higher than that of (111) crystal planes are positioned.

As an example, the control passivation layer 20 may be formed, for example, by a thermal growth method, a deposition method (for example, a chemical vapor deposition (PECVD) method, an atomic layer deposition (ALD) method). However, embodiments of the invention are not limited thereto, and the control passivation layer 20 may be formed by any of various methods.

A texturing process of a front surface of the semiconductor substrate 10 may be performed by any of various methods and any of various orders. For example, wet or dry texturing, or reactive ion etching (RIE) may be used.

The semiconductor layer 30 may be formed, for example, by a thermal growth method, a vapor deposition method (for example, low pressure chemical vapor deposition (LPCVD)), or the like. The first conductive region 32 may be formed by doping a portion of the semiconductor layer 30 with a first conductivity type dopant and the second conductive region 34 may be formed by doping another portion with a second conductivity type dopant. In this instance, an undoped region where the dopants are not doped are formed at the other portion where the first conductive region 32 and the second conductive region 34 are not formed, and the undoped region may constitute the barrier region 36. The front surface field region 130 may be formed by doping a second conductivity type dopant on the front surface of the semiconductor substrate 10. Any of various methods known as a doping process for forming the first and second conductive regions 32 and 34 and the front surface field region 130 may be used. For example, various methods, such as, an ion implantation method, a thermal diffusion method by performing a heat treatment using a gas containing a dopant, a heat-treatment method performed after forming a doping layer, and a laser doping method, may be applied. Embodiments of the invention are not limited thereto. In particular, the second conductive region 34 and the front surface field region 130 may be simultaneously formed by a thermal diffusion method using a gas including a second conductivity type dopant. This can greatly simplify the process. However, embodiments of the invention are not limited thereto, and the front surface field region 130 may be formed by a process different from a process of the second conductive region 34.

The front passivation layer 24, the anti-reflection layer 26, or the back passivation layer 40 may be formed by any of various methods, such as, a vacuum deposition method, a chemical vapor deposition method, a spin coating method, a screen printing method, a spray coating method, or so on. An order of forming the front passivation layer 24, the anti-reflection layer 26, and the back passivation layer 40 is not limited. The contact hole 46 may be formed by any of various methods using a laser ablation using a laser, an etching solution, etching paste, or so on.

Next, as shown in FIG. 4B, a metal layer 402 is formed entirely on the semiconductor layer 30 and the back passivation layer 40 so as to fill the contact holes 46. The metal layer 402 may be a single layer or may be a plurality of layers. The metal layer 402 may include a plurality of layers to satisfy various properties.

In the embodiment, the metal layer 402 may be formed by a sputtering method. According to the sputtering, the metal layer 402 can be formed with a small thickness by a simple process.

Next, as shown in FIG. 4C, a resist pattern 404 is formed on the metal layer 402 to correspond to portions where the first and second electrodes 42 and 44 will be formed. For example, the resist pattern 404 may be formed of a paste including a polymer resin (for example, an acrylic resin) and may be applied by a printing. However, embodiments of the invention are not limited thereto.

In this instance, when the polishing mark (that is, the concave portion C) formed on the back surface of the semiconductor substrate 10 goes beyond patterning reference lines RLs of first and second electrodes 42 and 44, the resist pattern 404 flows so as to fill an inside of the concave portion C and is positioned entirely in the concave portion C. As a result, the resist pattern 404 is also positioned outside the patterning reference line RL.

Next, as shown in FIG. 4D, a portion of the metal layer 402 (see FIG. 4C) on which the resist pattern 404 is not formed may be etched to form the first and second electrodes 42 and 44. In this instance, any of various materials capable of etching the metal layer 402 may be used as an etching material. As an example, an acid solution may be used as the etching material.

As described above, in the embodiment, the first and second electrodes 42 and 44 are patterned using the resist pattern 404 and the etching material, the second electrodes 42 and 44 can be formed while change in properties of other elements of the solar cell 100 can be minimized. Unlike in the embodiment, a patterning with a laser provides high heat to the first and second conductive regions 32 and 34 and the metal layer 402. Then, the first and second conductive regions 32 and 34 may be damaged or properties thereof may be changed, and a metal material of the metal layer 402 may be undesirably diffused into the first and second conductive regions 32 and 34. Particularly, when the metal layer 402 has a small thickness as in the embodiment, the problem caused by the laser may be serious if the patterning using the laser is used.

As described above, when the resist pattern 404 is positioned outside the pattering reference line RL by the concave portion C, the metal layer 402 may remain at the corresponding portion, and it may constitute a protrusion P of the first and second electrodes 42 and 44.

Then, as shown in FIG. 4E, the resist pattern 404 (see FIG. 4D) is removed. As a method for removing the resist pattern 404, any of various methods may be applied. For example, an alkaline solution (for example, a diluted potassium hydroxide (KOH)) may be used.

In the embodiment, the first and second electrodes 42 and 44 are formed by the etching process using the resist pattern 404 in the embodiment. Thus, the metal layer 402 has a small thickness by a sputtering method, and thus, the etching can be performed stably in a short period of time. Also, a material cost of the first and second electrodes 42 and 44 can be reduced. In addition, since the first and second electrodes 42 and 44 do not include separate pad portions for applying current for a plating method, the current loss due to the same can be prevented. In addition, it is possible to prevent the first and second conductive regions 32 and 34 from being damaged or changed in properties during the patterning process of the metal layer 402. In this instance, when the first and second electrodes 42 and 44 may have the linear shape, the resist pattern 404 can be stably applied to have a desired shape, and patterning can be performed so that the first and second electrodes 42 and 44 have a desired pattern. In addition, the first and second electrodes 42 and 44 can stably collect carriers with a large area. Accordingly, the solar cell 100 having excellent efficiency and reliability can be manufactured by a simple process.

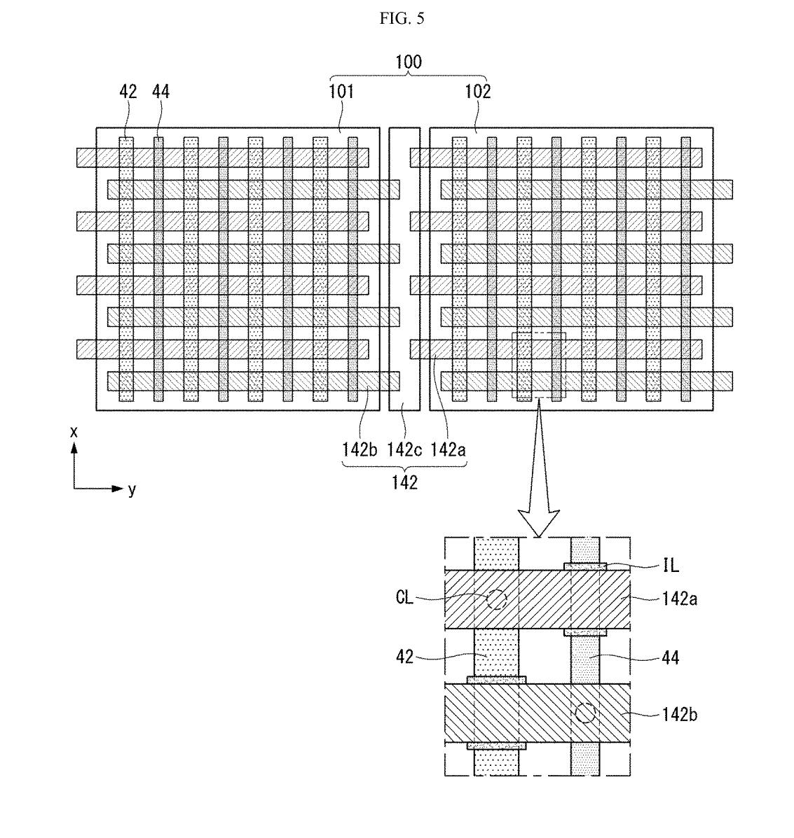

Hereinafter, a solar cell panel including a solar cell according to an embodiment of the invention will be described with reference to FIG. 5. In the following description, a solar cell and an inter-connector will be mainly described, and the description of other elements of the solar cell panel will be omitted.

FIG. 5 is a rear plan view showing a plurality of solar cells connected by an interconnector to be applied to a solar cell panel including a solar cell according to an embodiment of the invention.

Referring to FIG. 5, a plurality of solar cells 100 includes a first solar cell 101 and a second solar cell 102 connected by an interconnect 142.

More particularly, first electrodes 42 of the first solar cell 101 and second electrodes 44 of the second solar cell 102 may be connected by the interconnector 142 extending in a second direction crossing a first direction and including a plurality of first and second leads (or wirings) 142a and 142b. More particularly, in the embodiment, the interconnect 142 may include a first lead 142a which crosses and overlaps a plurality of first electrodes 42 provided in each of the first and second solar cells 101 and 102, and a second lead 142b which crosses and overlaps the plurality of second electrodes 44 in each of the first and second solar cells 101 and 102.

More particularly, the plurality of first leads 142a may be connected to the first electrodes 42 provided in each of the plurality of solar cells 101 and 102 through a conductive layer CL formed of a conductive material, and may be insulated from the second electrodes 44 through an insulating layer IL formed of an insulating material. Also, the plurality of second leads 142b may be connected to the second electrodes 44 provided in each of the plurality of solar cells 101 and 102 through a conductive layer CL, and may be insulated from the first electrodes 42 through an insulating layer IL. The conductive layer CL may be formed of a conductive adhesive or the like, and the insulating layer IP may be formed of any of various insulating materials. The first lead 142a connected to the first electrode 42 of the first solar cell 101 and the second lead 142b connected to the second electrode 44 of the second solar cell 102 may be connected by a connection portion 142c extending in the first direction.

The first and second leads 142a and 142b and the connection portion 142c may be formed of a conductive metal. For example, the first and second leads 142a and 142b and the connection portion 142c may include a conductive core and a conductive coating layer. The conductive core may include any one of gold (Au), silver (Ag), copper (Cu), and aluminum (Al). The conductive coating layer for coating the conductive core may include tin (Sn) or an alloy including tin (Sn). For example, the conductive core may be formed of copper (Cu), and the coating layer may be formed of SnBiAg, which is an alloy containing tin (Sn).

In the drawing, it is exemplified that the first and second leads 142a and 142b and the connection portion 142c are separately formed from and connected to each other. In this instance, the first and second leads 142a and 142b and the connection portion 142c may be connected to each other by a conductive adhesive. However, embodiments of the invention are not limited thereto, and the interconnector 142 including first and second leads 142a and 142b and the connection portion 142c may be formed as an integral structure. Widths of the first and second leads 142a and 142b are greater than widths of the first and second conductive regions 32 and 34, respectively.

The above-described features, structures, effects, and the like are included in at least one embodiment of the invention, and are not necessarily limited to only one embodiment. Further, the features, structures, effects and the like illustrated in the embodiments may be combined and modified by persons skilled in the art to which the embodiments are pertained. Therefore, it is to be understood that embodiments of the invention are not limited to these embodiments, and various combined and modified embodiments are included in a scope of the invention.

What is claimed is:

1. A solar cell, comprising:
a semiconductor substrate;
a control passivation layer on a surface of the semiconductor substrate;
a plurality of first conductive regions extending in a first direction on the control passivation layer and having a first conductivity type;
a plurality of second conductive regions extending in the first direction to be spaced apart from the plurality of first conductive regions on the control passivation layer and having a second conductivity type different from the first conductivity type;
a plurality of first electrodes electrically connected to the plurality of first conductive regions; and
a plurality of second electrodes electrically connected to the plurality of second conductive regions,
wherein the plurality of first conductive regions and the plurality of second conductive regions are spaced apart from an edge of the semiconductor substrate by a first interval,
wherein the plurality of first conductive regions and the plurality of second conductive regions are spaced apart from each other in a second direction crossing the first direction by a second interval, and
wherein the second interval is the same as or less than the first interval.

2. The solar cell of claim 1, further comprising:
a barrier region surrounding each of the plurality of first conductive regions and the plurality of second conductive regions on the control passivation layer to separate the plurality of first conductive regions and the plurality of second conductive regions from each other.

3. The solar cell of claim 1, wherein the first interval is in a range of approximately 100 μm to 500 μm, and
wherein the second interval is in a range of approximately 50 μm to 200 μm.

4. The solar cell of claim 1, wherein at least one of the plurality of first electrodes has a width smaller than a width of corresponding one of the plurality of first conductive regions, and has a length smaller than a length of the corresponding one of the plurality of first conductive regions,
wherein an entire portion of the at least one of the plurality of first electrodes overlaps the corresponding one of the plurality of first conductive regions,
wherein at least one of the plurality of second electrodes has a width smaller than a width of corresponding one of the plurality of second conductive regions, and has a length smaller than a length of the corresponding one of the plurality of second conductive regions, and
wherein an entire portion of the at least one of the plurality of second electrodes overlaps the corresponding one of the plurality of second conductive regions.

5. The solar cell of claim 4, further comprising:
a first distance between an edge of one of the plurality of first conductive regions and an edge of corresponding one of the plurality of first electrodes in the second direction; and
a second distance between an edge of one of the plurality of second conductive regions and an edge of corresponding one of the plurality of second electrodes in the second direction,
wherein the first distance and the second distance are one of the same as or less than the second interval.

6. The solar cell of claim 4, further comprising:
a first distance between an end of one of the plurality of first conductive regions and an end of corresponding one of the plurality of first electrodes in the first direction; and
a second distance between an end of one of the plurality of second conductive regions and an end of corresponding one of the plurality of second electrodes in the first direction,
wherein the first distance and the second distance are one of the same as or less than the second interval.

7. The solar cell of claim 4, wherein a width of the plurality of first conductive regions is larger than a width of the plurality of second conductive regions, and
wherein a distance between an edge of one of the plurality of first conductive regions and an edge of corresponding one of the plurality of first electrodes in the second direction is the same as or greater than a distance between an end of the one of the plurality of first conductive regions and an end of the corresponding one of the plurality of first electrodes in the first direction.

8. The solar cell of claim 4, wherein a width of the plurality of first conductive regions is larger than a width of the plurality of second conductive regions,
wherein a width of the plurality of first electrodes is greater than a width of the plurality of second electrodes, and
wherein a distance between an edge of one of the plurality of first conductive regions and an edge of corresponding one of the plurality of first electrodes in the second direction is greater than a distance between an edge of one of the plurality of second conductive regions and an edge of corresponding one of the plurality of second electrodes in the second direction.

9. The solar cell of claim 1, wherein the first interval is smaller than a width of the plurality of first conductive regions and a width of the plurality of second conductive regions in the second direction.

10. The solar cell of claim 1, wherein each of the plurality of first conductive regions, the plurality of second conductive regions, the plurality of first electrodes, and the plurality of second electrodes has a linear shape on the whole.

11. The solar cell of claim 1, wherein thicknesses of the plurality of first electrodes and the plurality of second electrodes are smaller than each of the first interval, the second interval, a width of the plurality of first conductive regions, a width of the plurality of second conductive regions, a width of the plurality of first electrodes, a width of the second electrodes, a distance between an end of one of the plurality of first or second conductive regions and an end of corresponding one of the plurality of first or second electrodes in the first direction, and a distance between an edge of one of the plurality of first or second conductive regions and an edge of corresponding one of the plurality of first or second electrodes in the second direction.

12. The solar cell of claim 1, wherein thicknesses of the plurality of first electrodes and the plurality of second electrodes are approximately 1 μm or less.

13. A solar cell, comprising:
a semiconductor substrate;
a control passivation layer on a surface of the semiconductor substrate;
a plurality of first conductive regions extending in a first direction on the control passivation layer and having a first conductivity type;
a plurality of second conductive regions extending in the first direction to be spaced apart from the plurality of first conductive regions on the control passivation layer and having a second conductivity type different from the first conductivity type;
a plurality of first electrodes electrically connected to the plurality of first conductive regions; and
a plurality of second electrodes electrically connected to the plurality of second conductive regions,
wherein a stepped portion is formed on the surface of the semiconductor substrate, and
wherein at least one of the plurality of first electrodes and the plurality of second electrodes has a linear shape on the whole and partially includes a protrusion protruding to correspond to the stepped portion of the semiconductor substrate.

14. The solar cell of claim 13, wherein the stepped portion is formed by a concave portion that is depressed into the semiconductor substrate by a polishing mark formed at the surface of the semiconductor substrate.

15. The solar cell of claim 13, wherein the protrusion has at least two sides that intersect with each other and are inclined to edges of the semiconductor substrate.

16. The solar cell of claim 14, wherein the protrusion has a triangular shape having a right angle or a quadrangular shape having two right angles.

17. The solar cell of claim 14, wherein the concave portion is formed of (100) planes, and
wherein a depth of the concave portion is greater than thicknesses of the plurality of first electrodes and the plurality of second electrodes.

18. A method for manufacturing a solar cell, the method comprising:
forming a control passivation layer on a surface of a semiconductor substrate;
forming a semiconductor layer on the control passivation layer, wherein the semiconductor layer comprises a plurality of first conductive regions extending in a first direction and having a first conductivity type, and a plurality of second conductive regions extending in the first direction to be spaced apart from the plurality of first conductive regions and having a second conductivity type different from the first conductivity type; and
forming an electrode including a plurality of first electrodes electrically connected to the plurality of first conductive regions and a plurality of second electrodes electrically connected to the plurality of second conductive regions,
wherein the forming of the electrode comprises:
forming an electrode layer on the semiconductor layer by sputtering;
forming a resist pattern on the electrode layer to correspond to a portion where the electrode is to be formed; and
etching a portion of the electrode layer where the resist pattern is not formed,
wherein a stepped portion is formed on the surface of the semiconductor substrate, and
wherein at least one of the plurality of first electrodes and the plurality of second electrodes has a linear shape on the whole and partially includes a protrusion protruding to correspond to the stepped portion of the semiconductor substrate.

19. The method of claim 18, wherein thicknesses of the plurality of first electrodes and the plurality of second electrodes are smaller than each of the first interval, the second interval, a width of the plurality of first conductive regions, a width of the plurality of second conductive regions, a width of the plurality of first electrodes, a width of the plurality of second electrodes, a distance between an end of one of the plurality of first or second conductive regions and an end of corresponding one of the plurality of first or second electrodes in the first direction, and a distance between an edge of one of the plurality of first or second conductive regions and an edge of corresponding one of the plurality of first or second electrodes in the second direction.

20. The method of claim 18, wherein thicknesses of the plurality of first electrodes and the plurality of second electrodes are approximately 1 μm or less.
